(19) United States
(12) Patent Application Publication
(10) Pub. No.: US 2020/0083453 A1
(43) Pub. Date: Mar. 12, 2020

(54) METHODS OF HANDLING A MASK DEVICE IN A VACUUM SYSTEM, MASK HANDLING APPARATUS, AND VACUUM SYSTEM

(71) Applicant: Applied Materials, Inc., Santa Clara, CA (US)

(72) Inventors: Sebastian Gunther ZANG, Mainaschaff (DE); Andreas SAUER, Großostheim (DE)

(21) Appl. No.: 15/745,791

(22) PCT Filed: Apr. 12, 2017
(86) PCT No.: PCT/EP2017/058826

§ 371 Date: Jan. 18, 2018

(51) Int. Cl. H01L 51/00; H01L 51/56; C23C 14/04; C23C 14/24

(52) U.S. Cl. CPC H01L 51/0012; H01L 51/56; C23C 14/24; H01L 51/0011; C23C 14/042; H01L 51/001

(57) ABSTRACT

A method of handling a mask device configured for masked deposition on a substrate is described. The method includes: loading a mask device into a vacuum system; attaching the mask device to a mask carrier in the vacuum system; and transporting the mask carrier that holds the mask device in a non-horizontal orientation along a transport path in the vacuum system. A further mask handling method includes: transporting a mask carrier that holds a mask device in a non-horizontal orientation along a transport path in a vacuum system; detaching the mask device from the mask carrier in the vacuum system; and unloading the mask device from the vacuum system. According to a further aspect, a mask handling assembly for handling a mask device as well as a vacuum system with at least one mask handling assembly are described.

### TECHNICAL FIELD

Embodiments of the present disclosure relate to methods of handling a mask device under vacuum, and particularly to methods of handling a mask device configured for masked deposition on a substrate in a vacuum system. Further embodiments relate to a mask handling assembly configured for handling a mask device in a vacuum system. More specifically, a mask handling assembly configured for handling mask devices configured for masked deposition on a substrate under vacuum is described. Further embodiments relate to a vacuum system with at least one mask handling assembly configured for handling mask devices in a vacuum system.

### BACKGROUND

Opto-electronic devices that make use of organic materials are becoming increasingly popular for a number of reasons. Many of the materials used to make such devices are relatively inexpensive, so organic opto-electronic devices have the potential for cost advantages over inorganic devices. The inherent properties of organic materials, such as their flexibility, may be advantageous for applications such as for the deposition on flexible or inflexible substrates. Examples of organic opto-electronic devices include organic light emitting devices (OLEDs), organic phototransistors, organic photovoltaic cells, and organic photodetectors.

For OLEDs, the organic materials may have performance advantages over conventional materials. For example, the wavelength at which an organic emissive layer emits light may be readily tuned with appropriate dopants. OLEDs make use of thin organic films that emit light when a voltage is applied across the device. OLEDs are becoming an increasingly interesting technology for use in applications such as flat panel displays, illumination, and backlighting.

Materials, particularly organic materials, are typically deposited on a substrate in a vacuum system under sub-atmospheric pressure. During deposition, a mask device may be arranged in front of the substrate, wherein the mask device may have at least one opening or a plurality of openings that define an opening pattern corresponding to a material pattern to be deposited on the substrate, e.g. by evaporation. The substrate is typically arranged behind the mask device during deposition and is aligned relative to the mask device. For example, a mask carrier may be used to transport the mask device into a deposition chamber of the vacuum system, and a substrate carrier may be used to transport the substrate into the deposition chamber for arranging the substrate behind the mask device.

It may be beneficial to remove used mask devices from the vacuum system at regular time intervals, e.g. for cleaning, mask exchange or maintenance of the used mask devices. Further, it may be beneficial to load mask devices to be used into the vacuum system at regular time intervals, e.g. for mask exchange or for providing clean or unused masks in the system. However, mask exchange is time-consuming and may lead to idle times of the system which increase the cost of ownership.

Accordingly, there is a need for a method and an apparatus for quick and efficient mask handling in a vacuum system. In particular, simplifying and accelerating the mask transport and mask exchange in a vacuum system configured for masked deposition on substrates would be beneficial.

### SUMMARY

In light of the above, methods of handling mask devices, a mask handling assembly as well as a vacuum system with at least one mask handling assembly are provided.

According to an aspect of the present disclosure, a method of handling a mask device configured for masked deposition on a substrate is provided. The method includes: loading a mask device into a vacuum system; attaching the mask device to a mask carrier in the vacuum system; and transporting the mask carrier that holds the mask device in a non-horizontal orientation along a transport path in the vacuum system.

According to a further aspect of the present disclosure, a method of handling a mask device configured for masked deposition on a substrate is provided. The method includes: transporting a mask carrier that holds a mask device in a non-horizontal orientation along a transport path in a vacuum system; detaching the mask device from the mask carrier in the vacuum system; and unloading the mask device from the vacuum system.

According to a further aspect of the present disclosure, a mask handling assembly for handling a mask device in a vacuum system is provided. The mask handling assembly includes: a mask holding portion configured for holding a mask device; a first actuator configured for a movement of the mask holding portion; and a handover mechanism configured for handing over the mask device in a non-horizontal orientation from the mask holding portion to a mask carrier, and/or vice versa.

According to a further aspect of the present disclosure, a vacuum system for depositing a material on a substrate is provided. The vacuum system includes: a mask handling chamber; a load lock chamber, wherein a closable opening is provided between the mask handling chamber and the load lock chamber; and a mask handling assembly, wherein a first actuator of the mask handling assembly is configured for moving a mask holding portion of the mask handling assembly between the mask handling chamber and the load lock chamber through the closable opening. The mask handling assembly further includes a handover mechanism configured for handing over the mask device in a non-horizontal orientation from the mask holding portion to a mask carrier, and/or vice versa. The handover mechanism or “transferring mechanism” may be a mechanism configured for magnetic attachment and detachment of the mask device.

According to a further aspect of the present disclosure, a vacuum system for depositing a material on a substrate is provided. The vacuum system includes: a mask handling chamber; at least one deposition chamber; and a mask transportation system configured for transporting mask devices to be used and used mask devices in a non-horizontal orientation between the mask handling chamber and the at least one deposition chamber, wherein the mask handling chamber comprises one of the following: (i) a mask handling assembly as described herein which is configured for handling the mask devices to be used and the used mask device, or (ii) a first mask handling area with a first mask handling assembly configured for handling the mask devices to be used and a second mask handling area with a second mask handling assembly configured for handling the used mask devices.

According to a further aspect of the present disclosure, a method of handling mask devices in a vacuum system is described. The method includes: providing a mask device to be used in a first mask handling area of a mask handling chamber; transporting the mask device to be used from the first mask handling area to at least one deposition chamber of the vacuum system, particularly while the mask device to be used is held by a mask carrier in a non-horizontal orientation; using the mask device to be used for masked deposition on a substrate in the at least one deposition chamber to provide a used mask device; transporting the used mask device from the deposition chamber to a second mask handling area of the mask handling chamber, particularly while the used mask device is held by the mask carrier in a non-horizontal orientation; and handling the used mask device in the second mask handling area.

Further aspects, advantages and features of the present disclosure are apparent from the description and the accompanying drawings.

### BRIEF DESCRIPTION OF THE D 1 WINGS

So that the manner in which the above recited features of the present disclosure can be understood in detail, a more particular description of the present disclosure, briefly summarized above, may be had by reference to embodiments. The accompanying drawings relate to embodiments of the disclosure and are described in the following. Typical embodiments are depicted in the drawings and are detailed in the description which follows.

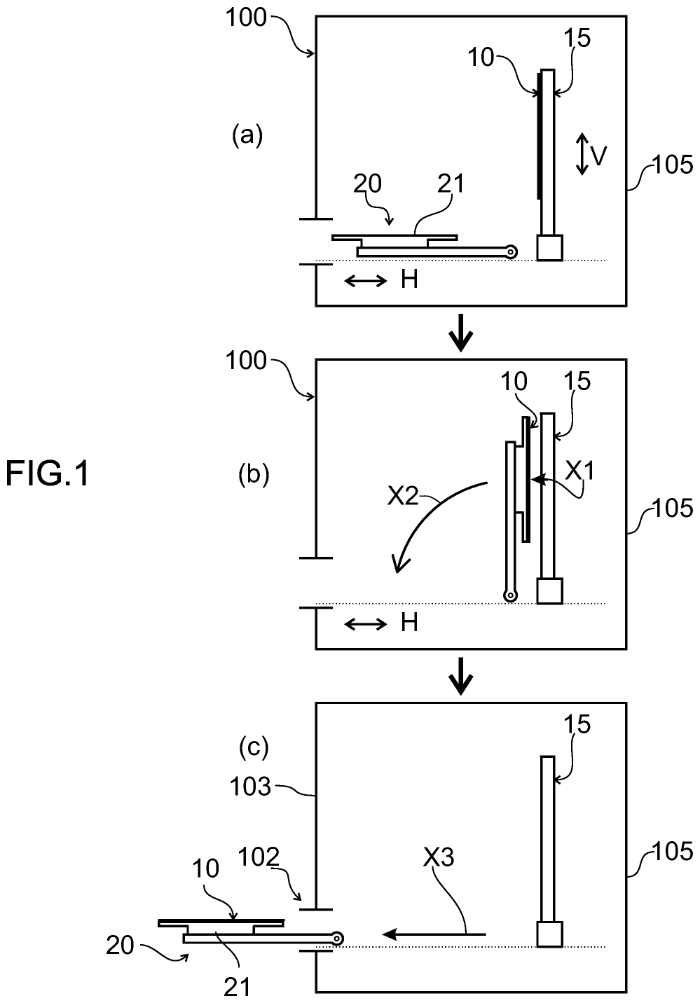

FIG. 1 is a schematic illustration of subsequent stages (a), (b), (c) of a mask handling method according to embodiments described herein;

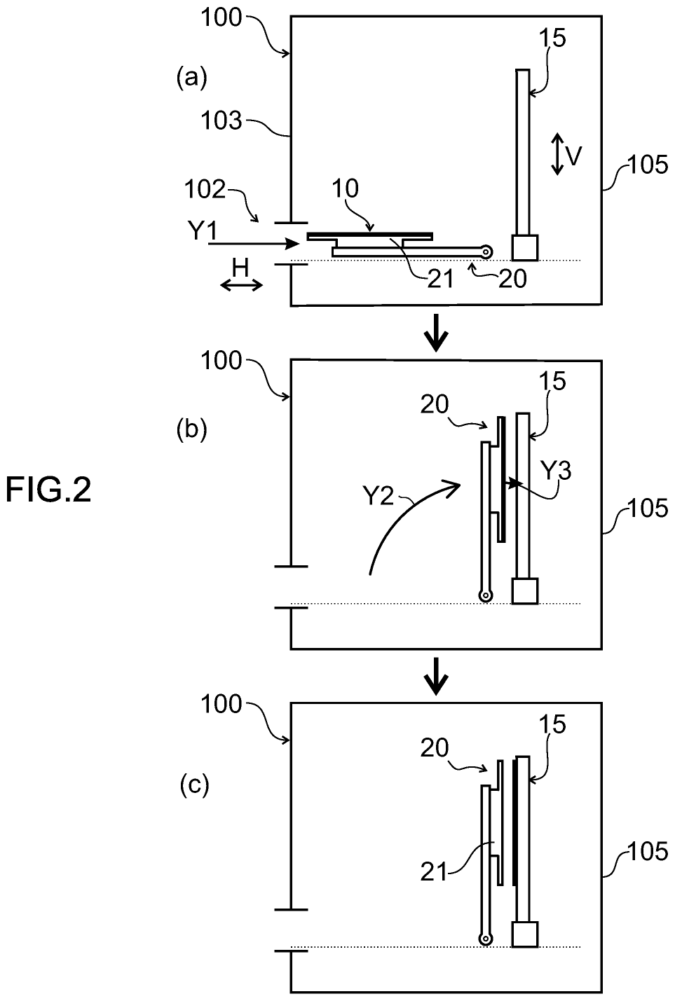

FIG. 2 is a schematic illustration of subsequent stages (a), (b), (c) of a mask handling method according to embodiments described herein;

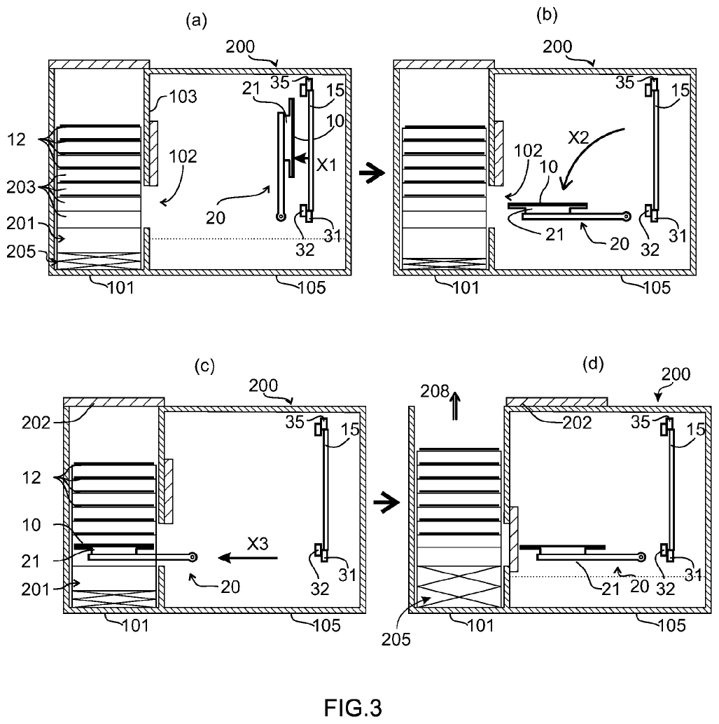

FIG. 3 is a schematic illustration of subsequent stages (a), (b), (c), (d) of a mask handling method with a mask handling assembly according to embodiments described herein;

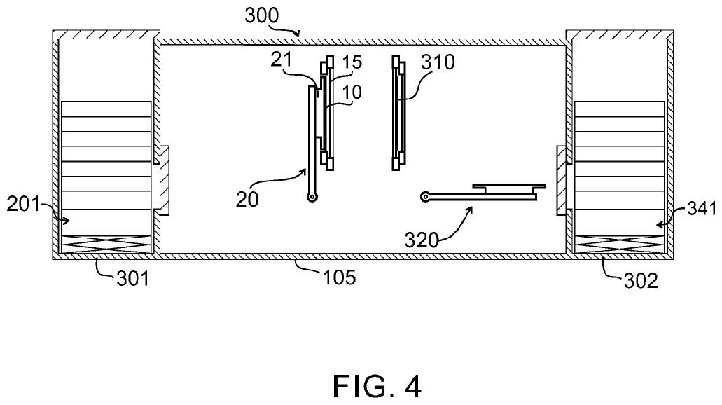

FIG. 4 is a schematic sectional view of a vacuum system according to embodiments described herein;

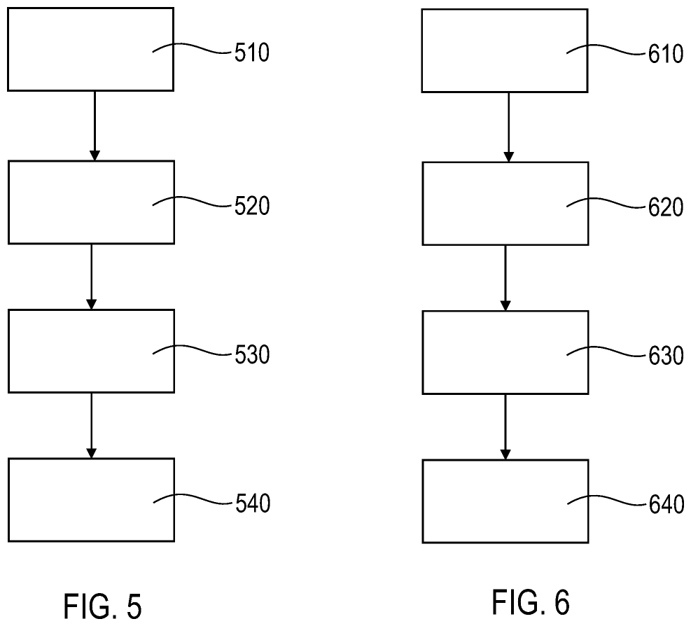

FIG. 5 is a flow diagram illustrating a method of mask handling according to embodiments described herein;

FIG. 6 is a flow diagram illustrating a method of mask handling according to embodiments described herein;

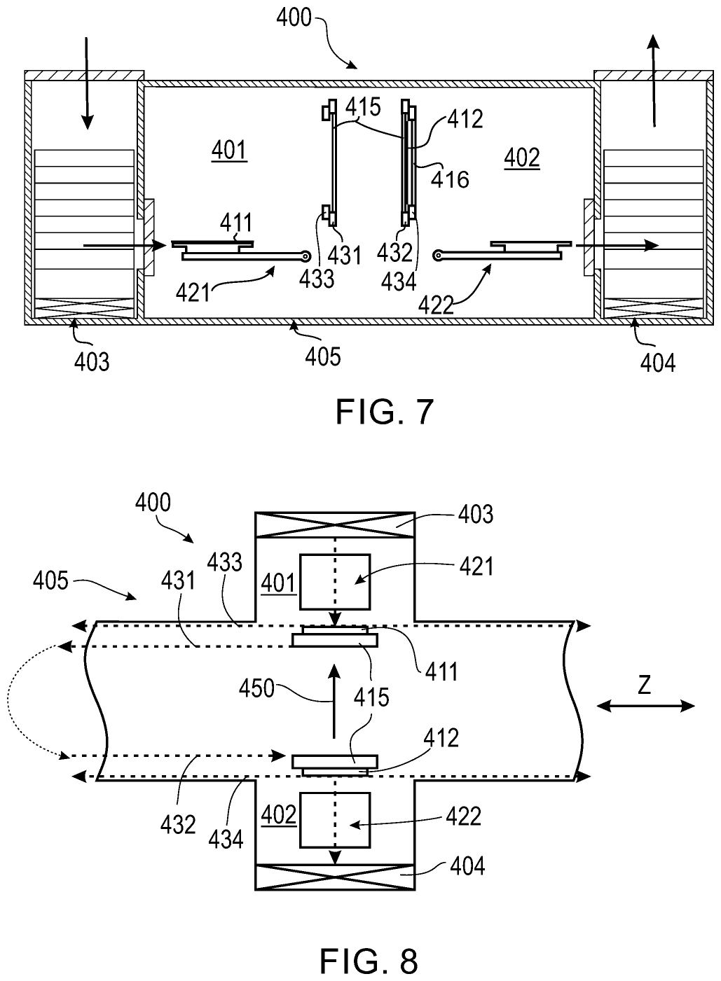

FIG. 7 is a schematic sectional view of a vacuum system according to embodiments described herein;

FIG. 8 is a schematic top view of a vacuum system according to embodiments described herein;

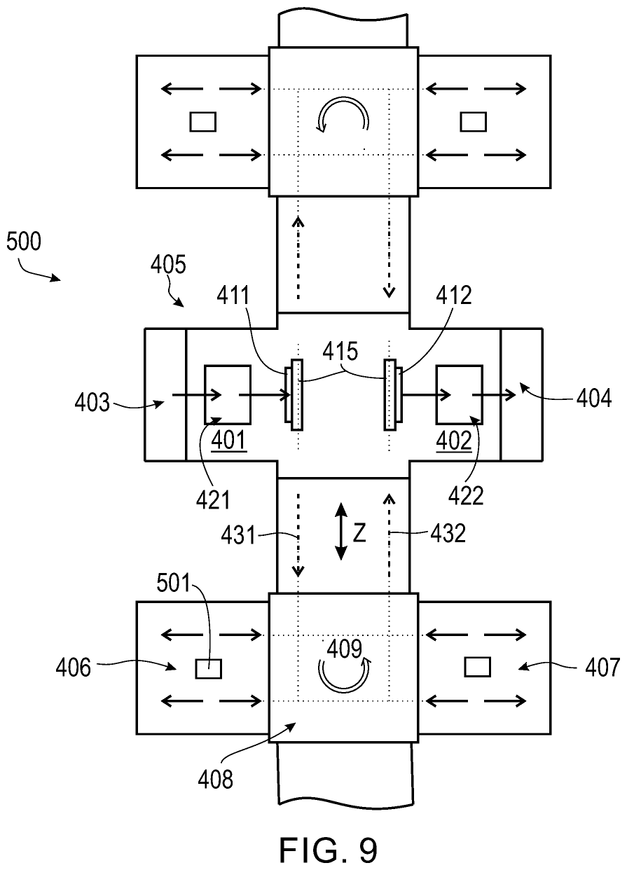

FIG. 9 is a schematic top view of a vacuum system according to embodiments described herein;

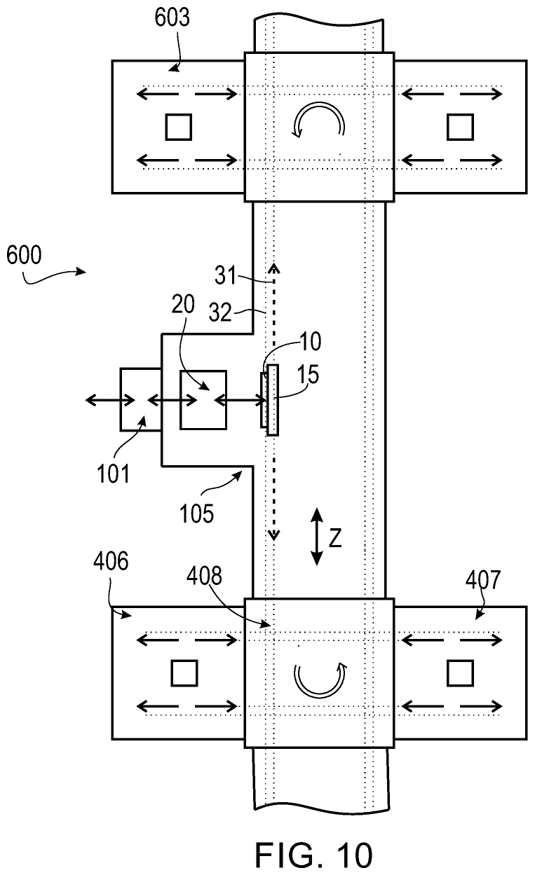

FIG. 10 is a schematic top view of a vacuum system according to embodiments described herein;

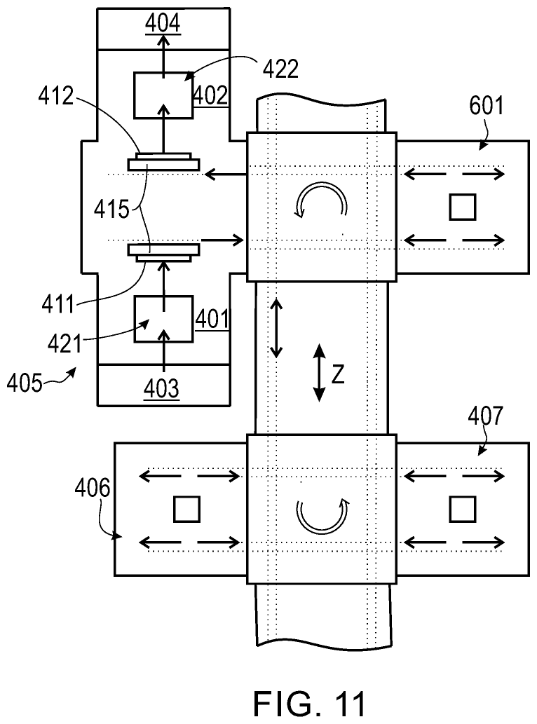

FIG. 11 is a schematic top view of a vacuum system according to embodiments described herein; and

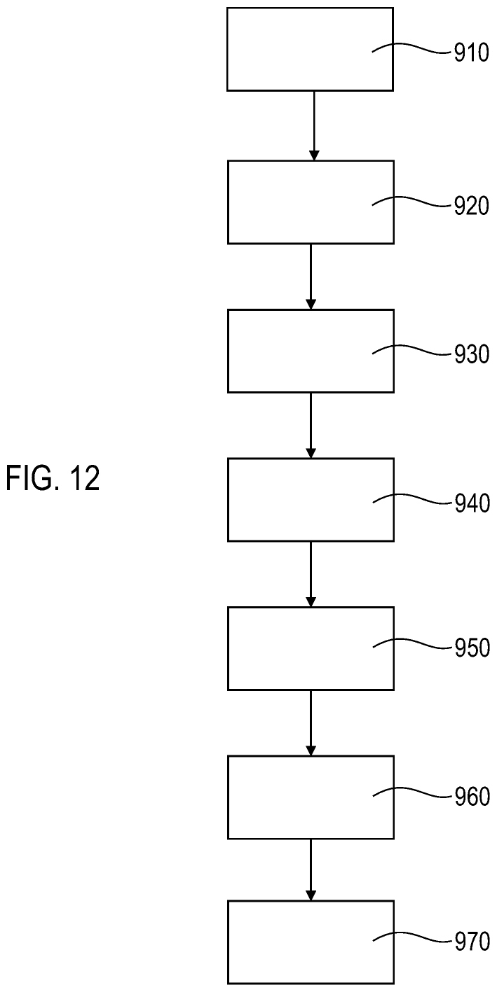

FIG. 12 is a flow diagram illustrating a method of mask handling according to embodiments described herein.

### DETAILED DESCRIPTION OF EMBODIMENTS

Reference will now be made in detail to the various embodiments, one or more examples of which are illustrated in the figures. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

FIG. 1 schematically illustrates subsequent stages (a), (b), (c) of a method of handling a mask device 10 according to embodiments described herein. The mask device 10 is configured for masked deposition on a substrate. In particular, the mask device 10 is configured to be arranged in front of a substrate that is to be coated with a material pattern defined by the mask device. For example, the mask device 10 may be configured for a masked evaporation process, wherein a material pattern is formed on a substrate by evaporation. The evaporated material may include organic compounds in some embodiments. For example, an OLED device may be manufactured.

In some embodiments, the mask device 10 may include a mask and a mask support. The mask support may be configured for supporting and holding the mask which is typically a delicate component. For example, the mask support may be a mask frame that surrounds the mask and has the shape of a frame. The mask may be permanently fixed to the mask frame, e.g. by welding, or the mask may be releasably fixed to the mask frame. A circumferential edge of the mask may be fixed to the mask frame.

The mask may include a plurality of openings formed in a pattern and configured to deposit a corresponding material pattern on a substrate by the masked deposition process. During deposition, the mask may be arranged at a close distance in front of the substrate or in direct contact with the front surface of the substrate. For example, the mask may be a fine metal mask (FMM) with a plurality of openings, e.g. 100.000 openings or more. For example, a pattern of organic pixels may be deposited on the substrate. Other types of masks are possible, e.g. edge exclusion masks.

In some embodiments, the mask device 10 may be at least partially made of a metal, e.g. of a metal with a small thermal expansion coefficient such as invar. The mask may include a magnetic material so that the mask can be magnetically attracted toward the substrate during deposition. Alternatively or additionally, the mask frame may include a magnetic material so that the mask device can be attracted to a mask carrier via magnetic forces.

The mask device 10 may have an area of 0.5 m² or more, particularly 1 m² or more. For example, a height of the mask device may be 0.5 m or more, particularly 1 m or more, and/or a width of the mask device may be 0.5 m or more, particularly 1 m or more. A thickness of the mask device may be 1 cm or less, wherein the mask frame may be thicker than the mask.

In some embodiments, the mask device 10 may be transported in the vacuum system, e.g. between two or more vacuum chambers of the vacuum system 100. For example, the mask device 10 may enter the vacuum system in a first vacuum chamber, e.g. in a mask handling chamber 105, and may be transported within the vacuum system toward a second vacuum chamber, e.g. toward a deposition chamber. One or more further vacuum chambers, e.g. transition chambers or routing chambers, may be arranged between the first vacuum chamber and the second vacuum chamber.

The mask device 10 may be held by a mask carrier 15 during the transport in the vacuum system 100. For example, the mask carrier 15 which holds the mask device 10 may be transported along a transport path in the vacuum system 100, e.g. from a first vacuum chamber to a second vacuum chamber. In some embodiments, the mask carrier 15 may be guided along mask tracks through the vacuum system. For example, the mask carrier 15 may include a guided portion configured to be guided along the mask tracks.

In some embodiments, the mask carrier 15 is transported by a mask transportation system, which may include a magnetic levitation system. For example, a magnetic levitation system may be provided so that at least a part of the weight of the mask carrier 15 may be carried by the magnetic levitation system. The mask carrier 15 can then be guided essentially contactlessly along mask tracks through the vacuum system. A drive for moving the mask carrier along the mask tracks may be provided.

The mask carrier 15 may hold the mask device 10 in a non-horizontal orientation (V) during the transport and/or during the deposition. For example, the mask device 10 may be held by the mask carrier 15 in an essentially vertical orientation during transport and/or during deposition.

An “essentially vertical orientation” as used herein may be understood as an orientation of the mask device 10, wherein an angle between a main surface of the mask device 10 and the gravity vector is between +10° and −10°, particularly between 0° and −5°. In some embodiments, the orientation of the mask may not be (exactly) vertical during transport and/or during deposition, but slightly inclined with respect to the vertical axis, e.g. by an inclination angle between 0° and −5°. A negative angle refers to an orientation of the mask device wherein the mask device is inclined downward. A deviation of the mask (and substrate) orientation from the gravity vector during deposition may be beneficial and might result in a more stable deposition process, or a facing down orientation might be suitable for reducing particles on the substrate during deposition. However, also an exactly vertical orientation (+/−1°) of the mask device 10 during transport and/or during deposition is possible.

Also a larger angle between the gravity vector and the mask device during transport and/or during deposition is possible. An angle between 0° and +/-80° may be understood as a “non-horizontal orientation of the mask device” as used herein. Transporting the mask device in a non-horizontal orientation may save space and allow for smaller vacuum chambers.

A mask holding surface of the mask carrier 15 may be essentially vertically oriented at least temporarily during the transport of the mask device. Holding a large area mask in an essentially vertical orientation is challenging, because the mask may bend due to the weight of the mask, the mask may slide down from the mask support surface in the case of an insufficient grip force, and/or the mask may move with respect to a substrate which may be arranged behind the mask during the deposition.

In stage (a) of FIG. 1, a vacuum system 100 is schematically depicted in a sectional view as a rectangle indicating the walls of a vacuum chamber. The vacuum system 100 may include a plurality of vacuum chambers which may be connected to each other by connection passages for mask carriers and/or for substrate carriers. Mask tracks for guiding the mask carriers may extend between two or more vacuum chambers of the vacuum system 100, and/or substrate tracks for guiding substrate carriers may extend between two or more vacuum chambers of the vacuum system 100.

A sub-atmospheric pressure may be provided in the vacuum system 100. For example, an inner volume of the vacuum system 100 may be pumped down to a pressure of 100 mbar or less, particularly 10 mbar or less, more particularly 1 mbar or less, or even a smaller pressure. In particular, a deposition chamber of the vacuum system may be provided at a low absolute pressure of 10 mbar or less during deposition. A mask handling chamber 105 may be provided at an absolute pressure of 10 mbar or less. In embodiments described herein, the mask device 10 may be handled in the vacuum system 100, particularly in the mask handling chamber 105, under vacuum.

As is depicted in stage (a) of FIG. 1, the mask device 10 is provided in the vacuum system 100, and the mask device 10 is held by a mask carrier 15 in a non-horizontal orientation V, particularly in an essentially vertical orientation. The mask device can be transported between the vacuum chambers of the vacuum system 100 while being held at the mask carrier 15. In some embodiments, the mask device 10 may be a used mask device that is to be unloaded from the vacuum system, e.g. for cleaning or exchange. For example, the mask device may have been used for the deposition on a substrate in a deposition chamber, and may be transported from the deposition chamber to the mask handling chamber along a transport path.

According to embodiments described herein, the mask device 10 is detached (X1) from the mask carrier 15 in the vacuum system 100 under vacuum, particularly in an evacuated mask handling chamber. The detachment (X1) of the mask device 10 from the mask carrier 15 is schematically depicted in stage (b) of FIG. 1.

A mask handling assembly 20 with a mask holding portion 21 may be provided for detaching the mask device 10 from the mask carrier 15 under vacuum. The mask handling assembly 20 may include a robot device such as a robot arm. The mask handling assembly 20 may be arranged in a vacuum chamber of the vacuum system 100, e.g. in the mask handling chamber 105.

In some embodiments, the mask handling assembly 20 may be configured for disconnecting a mechanical connection between the mask device 10 and the mask carrier 15. For example, the mask handling assembly 20 may include a robot device configured for untightening a screw connection, releasing a clamping connection or another mechanical connection between the mask device 10 and the mask carrier 15 under vacuum.

In some embodiments, the mask handling assembly 20 may be configured for releasing an electrostatic connection between the mask device 10 and the mask carrier 15. For example, during transport, the mask device may be held at the mask carrier by an electrostatic force generated by an electrostatic chucking device. The mask handling assembly 20 may be configured for deactivating the electrostatic force and/or for gripping the mask device with an own gripping force.

In some embodiments, the mask handling assembly 20 may be configured for releasing a magnetic connection between the mask device 10 and the mask carrier 15. For example, during transport, the mask device may be held at the mask carrier by a magnetic force generated by a magnetic chucking device of the mask carrier. The mask handling assembly 20 may be configured for deactivating the magnetic force and/or for gripping the mask device with an own gripping force.

In some embodiments, which may be combined with other embodiments described herein, the mask handling assembly 20 may include a handover mechanism configured for handing over the mask device 10 from the mask carrier 15 to the mask holding portion 21 of the mask handling assembly 20, and/or vice versa. The mask holding portion 21 of the mask handling assembly 20 may hold the mask device by a gripping force, e.g. at least one of a mechanical force, an electrostatic force and a magnetic force. In some embodiments, the mask handling assembly 20 may include a magnetic chuck configured for chucking the mask device toward the mask holding portion 21 of the mask handling assembly 20.

In some embodiments, which may be combined with other embodiments described herein, the mask device 10 is detached from the mask carrier 15 while the mask device 10 is held by the mask carrier 15 in a non-horizontal orientation (V), particularly in an essentially vertical orientation. For example, the mask device 10 is handed over from the mask carrier 15 to the mask holding portion 21 of the mask handling assembly 20 while the mask device 10 is in an essentially vertical orientation. The orientation of the mask carriers can therefore remain essentially constant during transport and mask detachment.

After detaching the mask device 10 from the mask carrier 15, the mask device 10 can be unloaded (X3) from the vacuum system 100.

In some embodiments, which may be combined with other embodiments described herein, the orientation of the mask device during unloading and/or loading of the mask device from the vacuum system is different than the orientation of the mask device while on the mask carrier.

For example, as is schematically depicted in stage (c) of FIG. 1, unloading may include moving the mask device 10 out of the vacuum system 100 along a mask unloading passage which may extend through a wall of the vacuum system 100. In some embodiments, the mask device 10 may be moved through a closable opening 102 provided in a side wall 103 of the mask handling chamber 105. The mask device 10 may be unloaded (X3) from the vacuum system via a load lock chamber. Unloading (X3) the mask device 10 from the vacuum chamber via the load lock chamber may be beneficial because there may be no need to flood the mask handling chamber 105 or the whole vacuum system. Rather, flooding of the load lock chamber may be sufficient.

The mask device 10 is detached (X1) from the mask carrier 15 in the vacuum system 100. Accordingly, only the mask device 10 is brought out of the vacuum system 100, whereas the mask carrier 15 can remain in the vacuum system 100. For example, the mask carrier 15 can be stored in a carrier storage inside the vacuum system, or a new mask device may be attached to the mask carrier 15 to be used for deposition.

Conventional methods of mask handling include the removal of the mask carriers from the vacuum system together with the mask devices attached thereto. The mask devices can then be detached from the mask carriers outside the vacuum system. However, the mask carriers typically have large and heavy carrier bodies so that the removal of the mask carriers with the attached mask devices from the vacuum system may be time-consuming and may rely on large load lock chambers. Further, large-scale and expensive lifting devices may be used for the transport of mask carriers out of a load lock chamber.

According to embodiments described herein, the mask device 10 is detached from the mask carrier 15 in the vacuum system 100, and the mask device 10 is moved out of the vacuum system 100 without the mask carrier 15 which may remain in the vacuum system for a longer time period.

Unloading (X3) the mask device from the vacuum system 100 may include moving the mask device 10 through a closable opening 102 of a vacuum chamber, e.g. the mask handling chamber 105, into a load lock chamber (not shown in FIG. 1). The closable opening 102 may be closed when the mask device is arranged in the load lock chamber, and the load lock chamber can be flooded, while the first vacuum chamber may remain under sub-atmospheric pressure. Thereupon, the mask device 10 may be taken out of the load lock chamber, e.g. by a lifting device.

In some embodiments, the mask device 10 is moved out of the mask handling chamber 105, while the mask device 10 is in a second orientation H different from the non-horizontal orientation V. The second orientation H may be an essentially horizontal orientation in some embodiments. For example, the mask device 10 may be translated through the closable opening 102 out of the mask handling chamber 105, while the mask device is in the essentially horizontal orientation.

An “essentially horizontal orientation” as used herein may be understood as an orientation in which an angle between the main surface of the mask device and a horizontal plane is 30° or less, particularly 20° or less, more particularly 10° or less, or wherein the mask device is arranged exactly horizontally (+/−1°).

Moving the mask device out of the mask handling chamber 105 in an essentially horizontal orientation may be beneficial because a comparably small opening in a side wall 103 of the mask handling chamber 105 may be sufficient for moving the mask device out of the mask handling chamber 105. For example, the closable opening 102 in the side wall of the mask handling chamber 105 may be a rectangular opening or a slit opening.

As is schematically depicted in stage (c) of FIG. 1, the mask device 10 may be moved out of the mask handling chamber 105 along an essentially linear transport path which may be a horizontal path, while the mask device 10 is arranged in an essentially horizontal orientation. For example, the mask handling assembly 20 may be configured for a movement, particularly for a translational movement, of the mask holding portion 21 through the closable opening 102 in the side wall 103.

In some embodiments, which may be combined with other embodiments described herein, the mask device 10 may be rotated (X2) from the non-horizontal orientation V to the second orientation H, before the mask device 10 is unloaded from the vacuum system 100. For example, the mask device may be detached (X1) from the mask carrier 15 in an essentially vertical orientation, may then be rotated (X2) from the essentially vertical orientation to the second orientation (H), and may then be unloaded (X3) from the vacuum system while the mask device is in the second orientation (H). Mask exchange can be accelerated.

The “rotation” of the mask device includes any kind of swinging or pivoting movement of the mask device. For example, the mask device may be swung through an arc between the non-horizontal orientation and the second orientation. In particular, the term “rotate” does not imply a rotation axis that extends through the mask device. Rather, the axis of rotation may be distant from the mask device, and may correspond to a pivot point of a mask handling assembly, e.g. a robot arm or swing module. In particular, the mask device may be swung up or down around an essentially horizontal axis.

A “rotation of a device” as used herein can be understood as a movement of the device from a first orientation to a second orientation different from the first orientation.

The mask handling assembly 20 may be configured for detaching the mask device 10 from the mask carrier 15, for rotating the detached mask device from the non-horizontal orientation to the second orientation, as well as for moving the rotated mask device out of the mask handling chamber 105, e.g. into a load lock chamber. In some embodiments, the mask handling assembly 20 includes a robot device such as a robot arm which is configured to grip the mask device, to rotate (or to swing) the gripped mask device around a rotation axis and to linearly translate the rotated mask device out of the mask handling chamber 105.

According to embodiments described herein, unloading used mask devices from the vacuum system can be accelerated and the mask handling can be simplified. In particular, large lifting devices for lifting the heavyweight mask carriers out of the vacuum system can be used less frequently. Rather, the lightweight mask devices can be automatically detached from the mask carriers by a robot device inside the vacuum system, and the detached mask devices may be taken from the vacuum system with a smaller transport device such as a lifting device which may be configured for lifting mask devices from a load lock chamber.

FIG. 2 schematically illustrates subsequent stages (a), (b), (c) of a method of handling a mask device 10 according to embodiments described herein. FIG. 1 relates to the detachment of a mask device from a mask carrier. FIG. 2 relates to the attachment of a mask device to a mask carrier in a vacuum system. Accordingly, the stages (a), (b), (c) of FIG. 2 are essentially inverted with respect to the stages (a), (b), (c) of FIG. 1. Details of the vacuum system and of the components provided therein depicted in FIG. 1 may be similar to the respective components as depicted in FIG. 2, so that reference can be made to the above explanations which are not repeated here.

It will be apparent that the mask attachment method of FIG. 2 and the mask detachment method of FIG. 1 can be combined. In particular, a mask device may first be handled according to the method of FIG. 2 for providing the mask device on a mask carrier in the vacuum system, and the mask device may then be handled according to the method of FIG. 1 for detaching the mask device from the mask carrier after use and for unloading the mask device from the vacuum system, e.g. for cleaning.

In stage (a) of FIG. 2, a mask device 10 is loaded (Y1) into the vacuum system 100. In stage (b) of FIG. 2, the mask device 10 is attached (Y3) to a mask carrier 15 under vacuum. In stage (c) of FIG. 2, the mask device 10 is held by the mask carrier 15 in a non-horizontal orientation (V). Thereupon, the mask carrier 15 which holds the mask device 10 in the non-horizontal orientation V can be transported along a transport path in the vacuum system 100, e.g. from a first vacuum chamber, such as the mask handling chamber 105, to a second vacuum chamber, such as a deposition chamber.

As is schematically depicted in stage (a) of FIG. 1, loading (Y1) the mask device 10 into the vacuum system 100 may include loading the mask device 10 into a mask handling chamber 105 of the vacuum system 100 without the mask carrier 15. Rather, the mask carrier 15 may already be arranged in the vacuum system 100, e.g. in the mask handling chamber 105 in a position for attaching a mask device. Cleaning and/or exchange of the mask devices 10 at regular time intervals may be beneficial, which may be done outside the vacuum system. On the other hand, the mask carriers 15 may remain in the vacuum system 100 for longer time periods.

As is shown in stage (a) of FIG. 1, loading (Y1) the mask device 10 into the vacuum system 100 may include moving the mask device 10 into a vacuum chamber of the vacuum system through a closable opening 102 in a side wall 103 of the vacuum chamber. The mask device 10 may be moved into the vacuum chamber via a load lock chamber (not shown in FIG. 2). In particular, in some embodiments, the mask device 10 may be translated through the closable opening 102 from the load lock chamber into the mask handling chamber 105.

In some embodiments, which may be combined with other embodiments described herein, a mask handling assembly 20 may be provided for moving the mask device 10 into the mask handling chamber, e.g. from the load lock chamber. The mask handling assembly 20 may include a robot device such as a robot arm with a mask holding portion 21 configured to be moved between the mask handling chamber 105 and the load lock chamber. The mask handling assembly 20 may be the mask handling assembly of FIG. 1. In other words, a single mask handling assembly may be configured both for attaching and detaching the mask devices from the mask carriers. Alternatively, two mask handling assemblies may be provided, e.g. a first mask handling assembly for performing the stages of FIG. 1 and a second mask handling assembly for performing the stages of FIG. 2.

In some embodiments, the mask device 10 is moved into the mask handling chamber 105 while the mask device 10 is in a second orientation H, e.g. an essentially horizontal orientation.

As is schematically depicted in stage (b) of FIG. 2, the mask device 10 may be rotated (Y2) from the second orientation H to the non-horizontal orientation (V), before attaching (Y3) the mask device 10 to the mask carrier 15. In particular, the mask device is moved into the mask handling chamber 105 in an essentially horizontal orientation, is rotated by the mask handling assembly to an essentially vertical orientation, and is attached to the mask carrier 15 in the essentially vertical orientation.

In some embodiments, the mask handling assembly 20 is arranged in the mask handling chamber 105. The mask handling assembly 20 may include a mask holding portion 21 configured for holding the mask device 10 in an essentially horizontal orientation and/or in an essentially vertical orientation. The mask handling assembly 20 may be configured for moving the mask device in an essentially horizontal direction into the mask handling chamber, and for rotating the mask device, e.g. from the essentially horizontal orientation to the essentially vertical orientation. Further, the mask handling assembly 20 may be configured for handing over the mask device 10 from the mask holding portion 21 of the mask handling assembly 20 to the mask carrier 15. In particular, the mask device 10 can be translated, rotated, and attached (and/or detached) by the mask handling assembly 20 which may include a robot arm that is configured for holding the mask device, e.g. by a magnetic force.

In stage (a) of FIG. 2, the mask device 10 may be moved through the closable opening 102 provided in the side wall 103 of the mask handling chamber 105 from a mask magazine or another mask storage device that is configured to store a plurality of mask devices. For example, the mask magazine may be arranged in a load lock chamber, and the mask holding portion of the mask handling assembly may move into the mask magazine through the opening.

In some embodiments, which may be combined with other embodiments described herein, the mask device 10 may be held at the mask carrier 15 by a magnetic force. In particular, the mask carrier 15 may include one or more electromagnets and/or permanent magnets configured for holding the mask device 10 at the mask carrier 15 in the non-horizontal orientation (V).

According to embodiments described herein, the comparably lightweight mask devices can be loaded from an ambient environment into the vacuum system, and the mask devices can be quickly attached to mask carriers in the vacuum system. Accordingly, the mask handling can be accelerated and idle times of the system can be reduced.

In particular, the mask frames of the mask devices can be disassembled from the mask carriers directly in the vacuum system. Therefore, only the mask device is to be transported outside the vacuum system, e.g. by overhead transport vehicles. The mask carriers will remain under vacuum together with the shield segments which can remain in the vacuum system for a much longer time than the mask devices. The maximum weight per mask that has to be handled outside the vacuum system decreases drastically, e.g. from about 300 kg or more of a mask carrier to 150 kg or less for a mask device without mask carrier. Therefore, typical overhead transport vehicles can easily transport 7 or more mask devices instead of a much smaller number of mask carriers. Mask exchange can be accelerated and the number of overhead transport systems, the number of mask carriers and/or the number of mask stockers can be reduced. Therefore, also costs can be reduced and space requirements can be improved. The mask carriers, e.g. together with shields mounted thereon, can remain under vacuum for a longer time and, therefore, the maintenance effort is significantly reduced. The mask carriers can be fed out to atmosphere when the shields are to be cleaned or exchanged. Therefore, the total number of mask carriers can be reduced.

According to embodiments described herein, mask devices and/or substrates are transported in the vacuum system in an essentially vertical orientation. The concept of a vertical transport allows the handling of bigger substrate sizes as compared to a concept wherein mask devices and/or substrates are transported and processed in an essentially horizontal orientation. The transport of the mask devices and/or of the substrates in the essentially vertical orientation can be facilitated by mounting the mask devices and/or the substrates to respective carriers. According to embodiments described herein, the attachment or the detachment of the mask devices to or from the mask carriers is not conducted under atmospheric conditions, but inside the vacuum system. Therefore, the weight that has to be handled outside the vacuum system can be reduced.

FIG. 3 is a schematic illustration of subsequent stages (a), (b), (c), (d) of a method of handling a mask device 10 according to embodiments described herein. The method of FIG. 3 is similar to the method of FIG. 1, so that reference can be made to the above explanations which are not repeated here.

FIG. 3 relates to the unloading of a mask device from a vacuum system 200. It will be apparent that the stages of FIG. 3 can be performed in an inverted sequence for loading a mask device into the vacuum system.

Stage (a) of FIG. 3 shows a vacuum system 200 including a plurality of vacuum chambers. One of the vacuum chambers is a mask handling chamber 105. A “vacuum chamber” (also referred to as “vacuum module”) as used herein may be understood as a specific area within a vacuum system than can be provided at a sub-atmospheric pressure. Typically, but not necessarily, a passage between two adjacent vacuum chambers or vacuum modules can be closed for service or maintenance of one vacuum chamber without flooding the adjacent vacuum chamber.

A mask handling assembly 20 for handling a mask device 10 is arranged in the mask handling chamber 105. A further vacuum chamber such as a load lock chamber 101 may be arranged adjacent to the mask handling chamber 105. A closable opening 102 may be provided in a side wall 103 between the mask handling chamber 105 and the load lock chamber 101.

A mask track 31 for guiding the mask carrier 15 through the vacuum system 200 may be provided in the mask handling chamber 105. The mask track 31 may extend from the mask handling chamber 105 toward one or more deposition chambers. The mask carrier 15 which holds a mask device may be transported along the mask track 31 between the mask handling chamber 105 and further vacuum chambers, e.g. one or more deposition chambers.

A mask transportation system for transporting the mask carrier along the mask track 31 may be provided. In some embodiments, the mask transportation system includes a magnetic levitation system 35 configured for holding at least a part of the weight of the mask carrier 15 by magnetic forces from above.

In stage (a) of FIG. 3, a mask device 10 that is held by a mask carrier 15 in a non-horizontal orientation (V) is provided in the mask handling chamber 105. The mask device 10 may be a used mask device that was used for masked deposition in a deposition chamber. The used mask device is to be detached from the mask carrier 15 and to be unloaded from the vacuum system 200, e.g. for cleaning, repair, maintenance, exchange, servicing or quality check.

The mask carrier 15 may carry the mask device 10 along the mask track 31 into the mask handling chamber 105, where the mask carrier 15 may stop in a position for detaching that is shown in stage (a) of FIG. 1. A mask handling assembly 20, e.g. including a robot arm, may be configured for a handover of the mask device 10 from the mask carrier 15 to the mask holding portion 21 of the mask handling assembly 20. As is schematically depicted in stage (a) of FIG. 3, the mask holding portion 21 may move toward the mask device 10, and the mask device 10 may be detached from the mask carrier and be captured by the mask holding portion 21.

In some embodiments, which may be combined with other embodiments described herein, also one or more substrate tracks 32 configured for the transport of substrate carriers may be provided in the mask handling chamber 105. The one or more substrate tracks 32 may be arranged at least partially between the mask tracks 31 and the mask handling assembly 20. Substrates which are held by substrate carriers may be guided along the substrate tracks 32 through the mask handling chamber 105. In this case, a detachment of the mask device 10 from the mask carrier 15 may be possible when no substrate carrier is arranged on the substrate track 32 between the mask track 31 and the mask handling assembly 20. The vertical dimension of the mask device 10 may be such that the mask device 10 can be moved by the mask handling assembly 20 across the one or more substrate tracks 32.

For example, the mask holding portion 21 may be configured for reaching through a space between upper and a lower substrate tracks to another side of the substrate tracks where the mask device 10 to be detached may be arranged. The vertical dimension of the mask device 10 may be smaller than the vertical dimension of a substrate carrier that is to be guided between the upper and lower substrate tracks so that the mask device 10 fits through the space between the upper and lower substrate tracks and can be moved across the substrate tracks to be unloaded from the system.

The mask device 10 may be held at the mask carrier 15 by a magnetic force which may be generated by a magnetic chuck of the mask carrier 15. The magnetic chuck may include one or more permanent magnets and/or one or more electromagnets. Detaching the mask device 10 from the mask carrier 15 may include changing a magnetic field that is generated by the magnetic chuck of the mask carrier 15. For example, a magnetic field generated by one or more magnets may be changed, reduced, inverted or deactivated.

Alternatively or additionally, detaching the mask device 10 from the mask carrier 15 may include reversing a polarity of at least one permanent magnet of the mask carrier 15 for releasing the mask device from the mask carrier. For example, the magnetic field of at least one permanent magnet may be reversed by inducing an electromagnetic field, e.g. via a coil that surrounds the at least one permanent magnet.

In some embodiments, which may be combined with other embodiments described herein, the mask handling assembly 20 supplies the mask carrier 15 with an electric current and/or an electric signal when the mask handling assembly 20 is in a position for detaching or attaching the mask device 10. For example, in the position for detaching or attaching the mask device 10, first exposed electrical contacts on the mask holding portion 21 may be brought into contact with second exposed electrical contacts on the mask carrier 15. For example, an output terminal of a power supply can then be electrically connected to an electromagnet of the mask carrier via the first and second exposed electrical contacts when the mask carrier is in the position for detaching or attaching. This has the advantage that the power supply may not be attached to the mask carrier. Rather, the power supply can be provided as a stationary component, e.g. outside the vacuum system, or as a component of the mask handling assembly 20. The electric current and/or the electric signal can be used for detaching or attaching the mask device from/to the mask carrier.

It will be apparent that the mask handling assembly can be used for attaching and/or detaching the mask device to/from the mask carrier. For example, attaching the mask device to the mask carrier may include providing an electrical current and/or an electrical signal to a chucking device of the mask carrier via the mask handling assembly. For example, the polarity of at least one permanent magnet of the mask carrier may be reversed for clamping the mask device to the mask carrier. The polarity of the at least one permanent magnet may be reversed by supplying an electromagnet temporarily with a current for providing an electromagnetic impulse. Exposed electrical contacts of the mask carrier may be used for the current supply in a position for attaching the mask device to the mask carrier.

As is depicted in stage (b) of FIG. 3, the detached mask device 10 may then be rotated or swung from the non-horizontal orientation (V) to the second orientation, e.g. an essentially horizontal orientation. For example, the mask handling assembly may have a second actuator configured for rotating or swinging the mask holding portion 21 around a rotation axis.

As is depicted in stage (c) of FIG. 3, the mask device 10 can then be unloaded from the vacuum system by moving the mask device 10 through the closable opening 102 in the side wall 103 of the mask handling chamber 105 into the further vacuum chamber, e.g. into the load lock chamber 101.

A mask magazine 201 for storing a plurality of mask devices 12 may be provided in the load lock chamber 101. The mask handling assembly 20 may be configured for moving a used mask device into a slot of the mask magazine 201 and/or for moving a mask device to be used from a slot of the mask magazine. The used mask device may be put into a slot of the mask magazine 201 by releasing the mask device from the mask holding portion 21 of the mask handling assembly 20 when the mask holding portion has been inserted into an empty slot of the mask magazine 201. A mask device to be used may be taken from a slot of the mask magazine 201 by attracting the mask device to the mask holding portion 21 of the mask handling assembly when the mask holding portion has been inserted into a slot of the mask magazine 201 where a mask device to be used is stored. The mask devices may be temporarily stored in the mask magazine 201. The mask handling assembly 20 may be configured for a linear movement of the mask devices into the slots and from the slots of the mask magazine 201.

In some embodiments, the mask magazine 201 may include a plurality of slots 203 for storing a plurality of mask devices 12. The plurality of slots 203 may be oriented essentially horizontally. Accordingly, the mask devices 10 can be moved into one of the slots and out of one of the slots in an essentially horizontal direction, e.g. by a linear movement.

This allows to stack the mask devices easily on top of each other in the mask magazine (or mask cassette system) after a linear movement of the mask holding portion in the horizontal direction. The use of mask cassette systems for the temporary storage and the transport of horizontally stacked mask devices may be quick and efficient.

In some embodiments, the mask magazine 201 may include a shifting mechanism 205 configured for a movement of the slots. For example, an occupied slot may be moved away from a position behind the closable opening 102, and an empty slot may be moved to a position behind the closable opening 102 so that the mask handling assembly 20 can insert a mask device into the empty slot. In some embodiments, the mask magazine includes a plurality of stacked slots which may be movable in a vertical direction. Accordingly, the plurality of stacked slots can be filled in sequence with used mask devices. Alternatively or additionally, the mask devices to be used can be taken in sequence from the plurality of stacked slots.

In stage (c) of FIG. 3, the mask device 10 is put by the mask handling assembly 20 through the closable opening 102 into an empty slot of the mask magazine 201. As is depicted in stage (d) of FIG. 3, the shifting mechanism 205 may then move the mask magazine 201, e.g. in a vertical direction, such that a new empty slot is positioned for the insertion of a further mask device.

Once the mask magazine 201 is filled with a predetermined number of used mask devices, the mask magazine 201 may be unloaded from the load lock chamber 101 into an atmospheric environment, as is indicated by arrow 208 in stage (d) of FIG. 3. For example, the mask magazine 201 may be lifted through an opening of the load lock chamber 101 by a lifting device. Alternative or additionally, a mask magazine 201 filled with mask devices to be used may be moved through the opening into the load lock chamber 101 by a lifting device.

The opening may be closable with a lid 202 so that the load lock chamber 101 can be provided at a sub-atmospheric pressure. For the removal and/or the insertion of the mask magazine 201 into the load lock chamber, the load lock chamber 101 may be flooded and the lid 202 can be opened, as is schematically depicted in stage (d) of FIG. 3.

The mask handling assembly 20 depicted in FIG. 3 is an example of a mask handling assembly according to embodiments described herein. The mask handling assembly 20 is configured for handling a mask device in a vacuum system and includes a mask holding portion 21 configured for holding the mask device, a first actuator configured for moving the mask holding portion 21 which may hold a mask device, and a handover mechanism configured for handing over the mask device 10 in a non-horizontal orientation (V) from the mask carrier 15 to the mask holding portion 21 and/or from the mask holding portion 21 to the mask carrier 15.

“Handling of a mask device” as used herein may be understood as at least one or more of attaching a mask device to a mask carrier, detaching a mask device from a mask carrier, loading or unloading a mask device into or from a vacuum system, moving, translating or rotating a mask device.

The first actuator may be configured for a translational movement of the mask holding portion 21, particularly between the mask handling chamber 105 and a second vacuum chamber, e.g. a load lock chamber 101. For example, the mask holding portion 21 which may hold a mask device can linearly move along an essentially horizontal direction between the mask handling chamber and the second vacuum chamber.

The mask handling assembly 20 may further be configured for gripping the mask device, e.g. for a handover of the mask device from the mask carrier, and for releasing the mask device, e.g. for depositing the mask device in a mask magazine which may be arranged in a load lock chamber.

The mask handling assembly 20 may be configured for holding the mask device at the mask holding portion 21, e.g. by a magnetic force. For example, one or more magnets, such as electromagnets and/or permanent magnets, may be integrated in the mask holding portion 21 for attracting a mask frame of the mask device toward the mask holding portion 21.

In some embodiments, the mask handling assembly includes a second actuator configured for a rotational movement of the mask holding portion 21 between the non-horizontal orientation, e.g. an essentially vertical orientation, and a second orientation, e.g. an essentially horizontal orientation.

In some embodiments, the handover mechanism is configured for triggering an attachment of the mask device 10 to the mask carrier 15, e.g. in order to hand over the mask device from the mask holding portion 21 to the mask carrier 15. Alternatively or additionally, the handover mechanism is configured for triggering a detachment of the mask device 10 from the mask carrier 15, e.g. in order to hand over the mask device from the mask carrier 15 to the mask holding portion 21.

In some embodiments, the handover mechanism may be configured for reversing a polarity of at least one permanent magnet provided at the mask carrier 15. Said reversal of the polarity may attract the mask device toward the mask carrier or may release the mask device from the mask carrier.

FIG. 4 is a schematic view of a vacuum system 300 for masked deposition of a material on a substrate. The vacuum system 300 may be suitable for being operated according to any of the methods described herein.

The vacuum system 300 includes a mask handling chamber 105, a load lock chamber 301, wherein a closable opening 102 is provided between the mask handling chamber 105 and the load lock chamber 301, and a mask handling assembly 20 according to any of the embodiments described herein.

The mask handling assembly 20 includes a first actuator configured for moving the mask holding portion 21 from the load lock chamber 301 to the mask handling chamber 105 and/or vice versa through the closable opening 102.

In some embodiments, the mask handling assembly 20 is configured for detaching used mask devices from mask carriers and for unloading the used mask devices from the vacuum system 300, e.g. by moving the detached mask devices from the mask handling chamber 105 into the load lock chamber 301 where a mask magazine 201 or another mask storage may be provided.

In some embodiments, the mask handling assembly 20 may also be configured for moving mask devices to be used from the load lock chamber into the mask handling chamber, e.g. from a mask magazine or another mask storage, and for attaching the mask devices to be used to mask carriers.

Alternatively, a second mask handling assembly 320 may be provided. The second mask handling assembly 320 may be configured for loading mask devices to be used 310 into the vacuum system 300, e.g. by moving the mask devices to be used 310 from a second load lock chamber 302 into the mask handling chamber 105. For example, the second mask handling assembly 320 may take the mask devices to be used 310 from a second mask magazine 341 provided in the second load lock chamber 302. The second mask handling assembly 320 may be configured for attaching the mask devices to be used 310 to mask carriers in the mask handling chamber 105.

FIG. 4 shows a vacuum system 300 including two mask handling assemblies, namely the mask handling assembly 20 and the second mask handling assembly 320. The mask handling assembly 20 and the second mask handling assembly may be arranged in different areas of a vacuum chamber, e.g. in the mask handling chamber 105.

The mask handling assembly 20 is configured for detaching used mask devices from mask carriers, and the second mask handling assembly 320 is configured for attaching mask devices to be used to mask carriers. The mask handling assembly 20 may be configured for moving used mask devices from the mask handling chamber 105, and the second mask handling assembly 320 may be configured for moving mask devices to be used into the mask handling chamber 105.

It is to be noted that the term “used mask device” may be replaced by the term “first mask device”, and the term “mask device to be used” may be replaced by the term “second mask device” in the present disclosure as appropriate.

In particular, the mask devices to be used and the used mask devices may be handled separately. The used mask devices may be handled in a first mask handling area of a mask handling chamber where the mask handling assembly 20 may be arranged, and the mask devices to be used may be handled in a second mask handling area of the mask handling chamber where the second mask handling assembly 320 may be arranged. A separate handling of mask devices may be useful, e.g. for reducing or avoiding a contamination of cleaned mask devices by coming close to used mask devices.

FIG. 5 is a flow diagram illustrating a method of mask handling according to embodiments described herein. In box 510, a mask device is loaded into a vacuum system. Loading the mask device in the vacuum system may include moving the mask device without a mask carrier from a load lock chamber into a mask handling chamber. For example, a mask handling assembly such as a robot device may be configured for moving the mask device into the mask handling chamber. The mask device may be translated in a horizontal direction into the mask handling chamber, while the mask device may be essentially horizontally oriented.

In box 520, the mask device is rotated to a non-horizontal orientation, particularly to an essentially vertical orientation. For example, the mask handling assembly such as a robot device may be configured for rotating the mask device.

In box 530, the mask device is attached to a mask carrier in the vacuum system, particularly while the mask device is in the non-horizontal orientation.

In box 540, the mask carrier that holds the mask device in the non-horizontal orientation is transported along a transport path in a vacuum system, e.g. from a mask handling chamber to a deposition chamber.

FIG. 6 is a flow diagram illustrating a method of mask handling according to embodiments described herein. The mask handling method of FIG. 6 may succeed the mask handling method of FIG. 5.

In box 610, a mask carrier that holds a mask device in a non-horizontal orientation is transported along a transport path in a vacuum system, e.g. from a deposition chamber to a mask handling chamber.

In box 620, the mask device is detached from the mask carrier in the vacuum system, particularly while the mask device is in the non-horizontal orientation.

In box 630, the mask device is rotated from the non-horizontal orientation to a second orientation, particularly to an essentially horizontal orientation. For example, a mask handling assembly such as a robot device may be configured for rotating the mask device.

In box 640, the mask device is unloaded from the vacuum system, particularly by moving the mask device without the mask carrier from a mask handling chamber into a load lock chamber. For example, a mask handling assembly such as a robot device may be configured for moving the mask device out of the mask handling chamber and into a mask magazine that is provided in the load lock chamber.

The unloaded mask device can then be cleaned or serviced outside the vacuum system.

According to another aspect described herein, a vacuum system 400 for masked deposition of a material on a substrate is provided.

FIG. 7 is a schematic sectional view of the vacuum system 400, and FIG. 8 is a top view of the vacuum system 400. The vacuum system 400 of FIG. 7 may be similar to the vacuum system 300 depicted in FIG. 4 so that reference can be made to the above explanations which are not repeated here. The vacuum system may be configured for depositing one or more materials on a substrate, e.g. by evaporation.

The vacuum system 400 includes a mask handling chamber 405, at least one deposition chamber (not shown in FIG. 7 and FIG. 8), and a mask transportation system configured for transporting mask devices in a non-horizontal orientation (V) between the mask handling chamber 405 and the at least one deposition chamber.

The mask handling chamber 405 includes a first mask handling area 401 with a first mask handling assembly 421 configured for handling mask devices to be used 411 and a second mask handling area 402 with a second mask handling assembly 422 configured for handling used mask devices 412.

“Mask devices to be used” as used herein may be understood as mask devices that are to be transported into at least one deposition chamber to be used for masked deposition on a substrate. In some embodiments, a mask device to be used may be a new mask device, a cleaned mask device or a mask device that has undergone service or maintenance.

“Used mask devices” as used herein can be understood as mask devices that have been used for masked deposition in a deposition chamber. The used mask devices are to be transported out of the deposition chamber, e.g. for cleaning or maintenance. For example, the used mask devices are to be unloaded from the vacuum system, e.g. for cleaning under atmospheric pressure. By using a mask device for masked deposition on one or more substrates, a mask device to be used becomes a used mask device. Typically, a mask device is used for masked deposition on ten or more substrates, whereupon the mask device may be cleaned. After cleaning, the mask device can be loaded again into the vacuum system to be used for masked deposition.

The second mask handling area 402 and the first mask handling area 401 may correspond to different sections of the mask handling chamber 405 that may be adjacent to each other or that may be spaced apart from each other. For example, the first mask handling area 401 and the second mask handling area 402 may be opposite parts of the mask handling chamber. In some embodiments, the first mask handling area 401 and the second mask handling area 402 are located on opposite sides of transport paths configured for the transport of the mask carriers 415. For example, as is schematically depicted in FIG. 7, the first mask handling area 401 may be located on a first side of first and second mask tracks and the second mask handling area 402 may be located on the opposite side of the first and second mask tracks.

According to some embodiments described herein, the mask devices to be used 411 can be handled, e.g. attached, detached, loaded, unloaded, stored, moved, rotated and/or translated, separately from the used mask devices 412. A contamination of cleaned mask devices can be reduced or avoided.

According to some embodiments, which can be combined with other embodiments described herein, a mask loading passage which extends to the first mask handling area 401 and a mask unloading passage which extends from the second mask handling area 402 may be provided. The mask loading passage may be spaced apart from the mask unloading passage. For example, the mask loading passage and the mask unloading passage may be provided on opposite sides of transport paths configured for the transport of the mask carriers 415. In particular, the mask loading passage and the mask unloading passage may be arranged on opposite sides of the mask handling chamber 405, as is schematically depicted in FIG. 7.

The mask loading passage may extend to the first mask handling area 401 and may be configured for loading the mask devices to be used 411 into the vacuum system 400, e.g. via a first load lock chamber 403. The mask unloading passage may extend from the second mask handling area 402 and may be configured for unloading the used mask devices 412 from the vacuum system 400, e.g. via a second load lock chamber 404.

In some embodiments, the mask loading passage extends via a first load lock chamber 403 into the first mask handling area 401. A first closable opening may be provided between the first mask handling area 401 and the first load lock chamber 403.

In some embodiments, the mask unloading passage extends from the second mask handling area 402 via a second load lock chamber 404. A second closable opening may be provided between the second mask handling area 402 and the second load lock chamber 404.

The first load lock chamber 403 and the second load lock chamber 404 may be provided adjacent to the mask handling chamber 405 on two opposite sides of the mask handling chamber 405. For example, as is schematically depicted in FIG. 7, the first load lock chamber 403 may be arranged on a first side of the mask handling chamber 405, and the second load lock chamber 404 may be arranged on a second side of the mask handling chamber 405 opposite the first side. In particular, the first load lock chamber 403 and the second load lock chamber 404 may be arranged on opposite sides of mask tracks configured for guiding mask carriers through the mask handling chamber 405.

In some embodiments, which may be combined with other embodiments described herein, the first mask handling assembly 421 may be configured for attaching the mask devices to be used 411 to mask carriers 415. For example, the first mask handling assembly may be similar to the mask handling assembly 20 shown in FIG. 2, so that reference can be made to the above explanations which are not repeated here.

In some embodiments, which may be combined with other embodiments described herein, the second mask handling assembly 422 may be configured for detaching the used mask devices 412 from the mask carriers 415. For example, the second mask handling assembly 422 may be similar to the mask handling assembly 20 shown in FIG. 1, so that reference can be made to the above explanations which are not repeated here.

By providing the first mask handling assembly 421 and the second mask handling assembly 422 for handling the mask devices in different areas of the vacuum system, the mask traffic within the vacuum system can be simplified and the mask handling can be accelerated. In particular, different areas within the mask handling chamber may be provided for handling the used mask devices and the mask devices to be used. This may reduce the complexity of the mask traffic in the vacuum system.

The complexity of the mask traffic in the vacuum system may be further reduced by providing a mask transportation system that includes a first mask track 431 for guiding mask carriers 415 that hold mask devices to be used 411 from the first mask handling area 401 toward the at least one deposition chamber, and/or that includes a second mask track 432 for guiding mask carriers 415 that hold used mask devices 412 to the second mask handling area 402 from the at least one deposition chamber.

By providing different mask tracks for mask devices to be used in the first mask handling area and for used mask devices in the second mask handling area, the first mask handling assembly 421 and the second mask handling assembly 422 may be operated independently. For example, a mask device may be attached to a mask carrier arranged on the first mask track 431 and a further mask device may be detached from a further mask carrier arranged on the second mask track 432, e.g. at the same time or subsequently. The mask devices can be handled quicker and more flexibly.

In some embodiments, which may be combined with other embodiments described herein, the mask transportation system may further include a translation mechanism 450 configured for translating mask carriers 415 within the mask handling chamber 405 from the second mask track 432 to the first mask track 431 and/or vice versa. Accordingly, a mask carrier can be directly translated from the second mask handling area 402 into the first mask handling area 401. A direct transfer of an empty mask carrier may be useful when a used mask device was detached from the mask carrier 415 in the second mask handling area, and a new mask device is to be attached to the mask carrier in the first mask handling area 401. Accordingly, an empty mask carrier can be used for transporting a further mask device. The transport path lengths for the mask carriers can be reduced and the mask traffic in the vacuum system can be accelerated.

A translation mechanism may be understood as a mechanism that is configured for translating a mask carrier between the first mask track 431 and the second mask track 432 in the mask handling chamber 405. For example, the mask carrier may be linearly moved between the first mask track 431 and the second mask track 432 in a direction that may be transverse or perpendicular to the directions of the first and second mask tracks.

For example, the translation mechanism 450 may include a drive and a carrier guide configured for translating a mask carrier between the first mask track and the second mask track. The mask tracks may run essentially parallel to each other through the mask handling chamber. The translation mechanism may move the mask carrier perpendicular to the direction of the mask tracks. In some embodiments, the translation mechanism 450 includes a magnetic levitation device configured for translating a mask carrier between the mask tracks.

Accordingly, in some embodiments, at least one loop transport path for the mask carriers may be provided. Namely, as is indicated in FIG. 8, a mask device to be used may be attached to a mask carrier in the first mask handling area 401, the mask carrier may be transported along the first mask track 431 toward the at least one deposition chamber (not shown in FIG. 8), the mask carrier may be transported along the second mask track 432 back to the mask handling chamber into the second mask handling area 402, and the used mask device may be detached from the mask carrier in the second mask handling area 402. Thereupon, in some embodiments, the (empty) mask carrier may be directly translated within the mask handling chamber into the first mask handling area with the translation mechanism 450, where a further mask device to be used may be attached to the mask carrier. The mask traffic can be simplified and carrier jams or interference between the mask carriers can be reduced.

In some embodiments, which may be combined with other embodiments described herein, the first mask track 431 extends essentially parallel to the second mask track 432 through the mask handling chamber 405. As is schematically depicted in FIG. 7 and FIG. 8, the first mask handling area 401 may be arranged on an outer side of the first mask track 431, and the second mask handling area 402 may be arranged on an outer side of the second mask track 432. In particular, the first mask handling apparatus and the second mask handling apparatus may be provided in opposite portions of the mask handling chamber 405, so that the first mask handling apparatus can handle mask devices that are transported along the first mask track 431, and the second mask handling apparatus can handle mask devices that are transported along the second mask track 432. For example, the first mask track 431 may include an attaching position. The mask carrier stops in the attaching position that is shown in FIG. 8, and a mask device is attached to the mask carrier while the mask carrier remains in the attaching position. The second mask track 432 may include a detaching position. The mask carrier stops in the detaching position that is shown in FIG. 8, and a mask device is detached from the mask carrier while the mask carrier remains in the detaching position.

In some embodiments, which may be combined with other embodiments described herein, the vacuum system 400 may further include a substrate transportation system configured for transporting substrates along a substrate transportation path in the vacuum system. In particular, the substrate transportation path may extend through the mask handling chamber 405 or past the mask handling assembly. A substrate can be transported along the substrate transportation path through the mask handling chamber 405, e.g. from a first deposition chamber which is arranged on a first side of the mask handling chamber to a second deposition chamber which is arranged on a second side of the mask handling chamber.

The mask handling chamber 405 may be provided in a main transportation path Z of the vacuum system 400 which extends in a main transport direction (e.g. up-down direction in FIG. 9). Substrate tracks for transporting substrate carriers and mask tracks for transporting mask carriers may run through the mask handling chamber in the main transport direction of the vacuum system 400. The substrates may be transported through the mask handling chamber 405 one or more times for being coated with a material stack, e.g. when two or more deposition chambers are arranged on different sides of the mask main transportation path Z.

By inserting the mask handling chamber 405 into the main transportation path Z of the vacuum system, the mask handling chamber may be used for the handling of mask devices that are used in two or more deposition chambers, particularly three or more deposition chambers, more particularly four or more deposition chambers. In some embodiments, at least two deposition chambers that are supplied with mask devices from the mask handling chamber are arranged on different sides of the mask handling chamber. Alternatively or additionally, at least two deposition chambers that are supplied with mask devices from the mask handling chamber are arranged on the same side of the mask handling chamber. In the latter case, a routing module may be provided for routing the mask devices into the correct deposition chamber. This concept of mask traffic will be explained in more detail below with reference to FIG. 9.

In some embodiments, which may be combined with other embodiments described herein, the main transportation path Z of the vacuum system includes four or more tracks, including a first mask track 431, a second mask track 432, a first substrate track 433 and a second substrate track 434. Further tracks may be provided. The tracks may extend parallel to each other in the main transport direction of the vacuum system. The first substrate track 433 and the second substrate track 434 may be provided as outer tracks, and the first mask track 431 and the second mask track 432 may be provided as inner tracks that are arranged between the substrate tracks. Other arrangements are possible.

In some embodiments, said four or more tracks of the main transportation path Z may extend through the mask handling chamber 405, e.g. essentially parallel to each other. The four tracks are schematically depicted in FIG. 7 in a sectional view. The first mask handling assembly 421 may be configured for handling a mask device that is held by a mask carrier on the first mask track 431 in the mask attaching position. The second mask handling assembly 422 may be configured for handling a mask device that is held by a mask carrier on the second mask track 432 in the mask detaching position.

In FIG. 7, a substrate carrier 416 is arranged on the second substrate track 434 between a mask carrier 415 and the second mask handling assembly 422. When the substrate carrier 416 has moved away from the depicted position, the second mask handling assembly 422 can detach the mask device from the mask carrier and move the mask device across the second substrate track 434. Similarly, the first mask handling assembly 421 may be configured for detaching and/or moving a mask device across the first substrate track 433.

The handling of the mask devices to be used in the first mask handling area 401 of the vacuum system 400 may be similar or identical to the mask handling in the vacuum system 100 shown in FIG. 2, so that reference can be made to the above explanations which are not repeated here.

Similarly, the handling of the used mask devices in the second mask handling area 402 of the vacuum system 400 may be similar or identical to the mask handling in the vacuum system 100 shown in FIG. 1 or the vacuum system 200 shown in FIG. 3, so that reference can be made to the above explanations which are not repeated here.

FIG. 9 is a top view of a vacuum system 500 in accordance with embodiments described herein. The mask handling chamber 405 of the vacuum system 500 may be similar or identical to the mask handling chamber of the vacuum system 400 shown in FIG. 7, so that reference can be made to the above explanations which are not repeated here.

The vacuum system 500 includes the mask handling chamber 405, at least one deposition chamber 406 and a second deposition chamber 407. The at least one deposition chamber 406 and the second deposition chamber 407 may be arranged on the same side of the mask handling chamber 405, e.g. on the lower side in FIG. 9. In some embodiments, further deposition chambers may be arranged on the other side of the mask handling chamber 405, e.g. on the upper side in FIG. 9.

A first substrate track and a second substrate track may extend through the mask handling chamber 405 so that substrates held by substrate carriers can be transported between any of the deposition chambers, as appropriate.

In other embodiments, e.g. in the embodiment of FIG. 11, no substrate tracks may extend through the mask handling chamber 405. For example, in the embodiment of FIG. 11, the mask handling chamber 405 may be arranged at a side of the main transportation path Z of the vacuum system. The mask carriers 415 may be routed into the mask handling chamber 405 via a rotation module from the main transportation path Z.

The mask handling chamber 405 of FIG. 11 may essentially correspond to the mask handling chamber shown in FIG. 4. However, no substrate tracks may be arranged adjacent to the first and second mask handling assemblies. The mask and substrate traffic along the main transportation path Z may accelerated by handling the masks at positions which are spaced apart from the main mask tracks which extend along the main transportation path Z of the system. For example, side mask tracks for assembling and disassembling the mask devices from the mask carriers may be provided.

In the exemplary embodiment of FIG. 11, two side mask tracks may be provided in the mask handling chamber 405 which may extend transversely, in particular perpendicular, to the main mask tracks of the main transportation path Z of the vacuum system. A first mask handling area 401 for handling masks to be used 411 may be arranged adjacent to the first mask track and a second mask handling area 402 for handling used mask devices 412 may be arranged adjacent to the second mask track. In some embodiments, the mask handling chamber may be arranged directly adjacent to a rotation chamber configured for rotating the mask carriers 415. A further deposition chamber 602 may be arranged on the opposite side of the routing chamber in some embodiments.

It is to be noted that, in some embodiments, the first mask handling area 401 for handling masks to be used 411 may be arranged on a first side of a rotation chamber, and the second mask handling area 402 for handling used mask devices 412 may be arranged on a second side of the rotation chamber, e.g. opposite the first side. For example, the first mask handling area and the second mask handling area may be arranged on two opposite sides of the main transportation path Z. A first mask handling assembly may be arranged in the first mask handling area, and a second mask handling assembly may be arranged in the second mask handling area at a distance from the first mask handling area. A first side mask track may extend into the first deposition area, e.g. perpendicular to the first main mask track, and a second side mask track may extend into the second deposition area, e.g. perpendicular to the second main mask track.

In particular, the mask handling chamber (or “mask handling module”) may comprise a rotation chamber as an integral part thereof. In other words, the first mask handling area 401, the second mask handling area 402, and any vacuum transit chamber, e.g. a rotation chamber or routing chamber, arranged therebetween, may constitute the mask handling chamber (or “mask handling module”) according to embodiments described herein. For example, a mask handling chamber may comprise several sub-chambers arranged next to each other. In some embodiments, the main transportation path Z of the vacuum system may extend at least through one sub-chamber of the mask handling module.

In some embodiments, e.g. as exemplarily shown in FIG. 11, a further deposition chamber 601 may be arranged on an opposite side of the main transportation path Z of the vacuum system with respect to the mask handling chamber 405. Further, a routing module may be arranged between the further deposition chamber 601 and the mask handling chamber 405.

In some embodiments, which can be combined with other embodiments described herein, the vacuum system 500 may further include a routing chamber 408 which is arranged between the mask handling chamber 405, the at least one deposition chamber 406 and the second deposition chamber 407 (see, for example, FIG. 9). The routing chamber 408 may include a routing device 409, e.g. a rotation device, configured for routing the mask devices to be used 411 and the used mask devices 412 between the mask handling chamber 405 and the at least one deposition chamber 406, as well as between the mask handling chamber 405 and the second deposition chamber 407. For example, an orientation of the at least one deposition chamber 406 and of the second deposition chamber 407 may be perpendicular with respect to the main transportation path Z of the vacuum system, so that the mask carriers and the substrate carriers are to be rotated around an essentially vertical rotation at an intersection between the main transportation path Z and the deposition chambers. The mask carriers and/or the substrate carriers may be rotated in the routing chamber 408.

In some embodiments, further deposition chambers, transition chambers and/or routing chambers may be provided on the other side of the mask handling chamber 405, e.g. on the upper side in FIG. 9. The mask handling chamber 405 may be configured for supplying each of said deposition chambers with mask devices to be used and for handling the used mask devices from each of said deposition chambers. The complexity of the mask traffic in a vacuum system can be reduced and the mask exchange can be accelerated.

In some embodiments, an evaporation source 501 may be provided in the at least one deposition chamber 406 for masked deposition of a material on the substrate. The present disclosure is however not restricted to vacuum systems with an evaporation source. For example, chemical vapor deposition (CVD) systems, physical vapor deposition (PVD) systems, e.g. sputter systems, and/or evaporation systems were developed to coat substrates, e.g. thin glass substrates, e.g. for display applications, in a deposition chamber. In typical vacuum systems, the substrates may be held by substrate carriers, and the substrate carriers may be transported through the vacuum chamber by a substrate transport system. The substrate carriers may be moved by the substrate transport system such that at least a part of the main surfaces of the substrates are exposed toward coating devices, e.g. a sputter device or an evaporation source. The main surfaces of the substrates may be coated with a thin coating layer, while the substrates may be positioned in front of an evaporation source 501 which may move past the substrate at a predetermined speed. Alternatively, the substrate may be transported past the coating device at a predetermined speed.

The substrate may be an inflexible substrate, e.g., a wafer, slices of transparent crystal such as sapphire or the like, a glass substrate, or a ceramic plate. However, the present disclosure is not limited thereto and the term substrate may also embrace flexible substrates such as a web or a foil, e.g. a metal foil or a plastic foil.

The substrate may be a large area substrate in some embodiments. A large area substrate may have a surface area of 0.5 m² or more. Specifically, a large area substrate may be used for display manufacturing and be a glass or plastic substrate. For example, substrates as described herein shall embrace substrates which are typically used for an LCD (Liquid Crystal Display), a PDP (Plasma Display Panel), and the like. For instance, a large area substrate can have a main surface with an area of 1 m² or larger. In some embodiments, a large area substrate can be GEN 4.5, which corresponds to about 0.67 m² substrates (0.73×0.92 m), GEN 5, which corresponds to about 1.4 m² substrates (1.1 m×1.3 m), or larger. A large area substrate can further be GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. In some implementations, an array of smaller sized substrates with surface areas down to a few cm², e.g. 2 cm×4 cm and/or various individual shapes may be positioned on a single substrate support. The mask devices may be larger than the substrates in some embodiments in order to provide for a complete overlap with the substrates during deposition.

In some implementations, a thickness of the substrate in a direction perpendicular to the main surface of the substrate may be 1 mm or less, e.g. from 0.1 mm to 1 mm, particularly from 0.3 mm to 0.6 mm, e.g. 0.5 mm. Even thinner substrates are possible.

FIG. 10 is a schematic top view of a vacuum system 600 for masked deposition of a material on a substrate according to some embodiments described herein. The vacuum system 600 includes a mask handling chamber 105, at least one deposition chamber 406, and a mask transportation system configured for transporting mask devices 10 in a non-horizontal orientation between the mask handling chamber 105 and the at least one deposition chamber 406. The term “mask handling chamber” as used herein may refer to a specific section of a vacuum system where mask devices are handled and may include several sub-chambers.

As is schematically depicted in FIG. 10, a mask handling assembly 20 according to any of the embodiments described herein is arranged in the mask handling chamber 105. The mask handling assembly 20 may be configured for handling mask devices to be used and for handling used mask devices. Handling mask devices may include at least one or more of moving mask devices into the mask handling chamber, rotating mask devices, translating mask devices, attaching mask devices to mask carriers, detaching mask carriers from mask devices and/or moving mask devices out of the vacuum chamber.

The vacuum system 600 may further include at least one load lock chamber 101. The mask handling assembly 20 may be configured for moving mask devices between the load lock chamber 101 and the mask handling chamber 105. In some embodiments, at least one mask magazine such as a mask stocker device or a mask cassette may be provided in the load lock chamber 101. The mask handling assembly 20 may be configured for moving mask devices from the mask stocker and into the mask stocker device from the mask handling chamber.

In some embodiments, two or more load lock chambers may be provided, e.g. a first load lock chamber with a first mask magazine for mask devices to be used and a second load lock chamber with a second mask magazine for used mask devices. The mask handling assembly 20 may be configured for moving mask devices from and into both the first and the second load lock chambers.

The vacuum system 600 may be similar to the vacuum system 200 depicted in FIG. 2, so that reference can be made to the above explanations which are not repeated here.

A mask track 31 for guiding a mask carrier 15 through the vacuum system 600 along a main transport direction may extend past the mask handling assembly 20. The mask handling assembly 20 may be positioned such that a mask device 10 can be handed over from a mask holding portion 21 of the mask handling assembly 20 to a mask carrier 15 which is positioned on the mask track 31 at a mask attaching position. Further, a mask device 10 can be handed over from the mask carrier 15 to the mask holding portion 21 of the mask handling assembly 20.

In some embodiments, which can be combined with other embodiments described herein, the mask handling assembly 20 is configured for moving a mask device 10 from the load lock chamber 101 into the mask handling chamber 105, and for attaching the mask device to the mask carrier 15 under vacuum while the mask device is in a non-horizontal orientation. Further, the mask handling assembly 20 is configured for detaching the mask device from the mask carrier 15 under vacuum while the mask device is in a non-horizontal orientation, and for moving the mask device from the mask handling chamber 105 into the load lock chamber 101 or into a further load lock chamber.

The mask carrier 15 with the attached mask device 10 can be transported along the mask track 31 along the main transportation path Z of the vacuum system 600 toward a deposition chamber, e.g. toward the at least one deposition chamber 406 or toward the second deposition chamber 407. In some embodiments, at least one of further vacuum chamber, e.g. a transition chamber or a routing chamber 408, may be arranged between the mask handling chamber 105 and the deposition chamber. In the routing chamber 408, the mask carrier can be rotated towards the deposition chamber. In the deposition chamber, the mask device 10 may be used for masked deposition on a substrate. Thereafter, the mask carrier may be transported from the deposition chamber back into the mask handling chamber 105, e.g. along the mask track 31 along the main transportation path Z.

When the mask carrier has arrived at the mask detaching position next to the mask handling assembly 20, the mask device can be detached from the mask carrier by the mask handling assembly 20 and unloaded from the vacuum system.

In some embodiments, a substrate track 32 may extend parallel to the mask track of 31, e.g. between the mask track 31 and the mask handling assembly 20. In this case, a mask holding portion of the mask handling assembly 20 may be movable across the substrate track 32 in order to attract the mask device 10 to the mask holding portion 21.

By providing a single mask handling assembly handling both the mask devices to be used and the used mask devices, space requirements and costs can be reduced.

In some embodiments, the main transportation path Z of the vacuum system 600 may include four tracks, namely two outer tracks which may be substrate tracks and two inner tracks which may be mask tracks or vice versa. The mask handling assembly 20 may be configured to supply a predetermined number of deposition chambers (e.g. four deposition chambers in FIG. 10) with mask devices. In order to reduce the transportation distances for the mask carriers, the mask handling chamber 105 may be arranged adjacent to the main transportation path Z in a middle section between at least two deposition chambers. Accordingly, mask carriers may be moved from the mask handling chamber in both directions of the main transportation path Z (e.g., upward and downward in FIG. 10).

Substrate carriers can be transported along the substrate tracks independently of the mask carriers which are transported on the mask tracks. In some embodiments, substrate carriers are transported along the substrate track 32 in only one direction, e.g. from the deposition chamber 603 toward the at least one deposition chamber 406. In particular, the substrates to be coated may enter the vacuum system 600 on a first side of the main transportation path Z, and the coated substrates may be unloaded from the vacuum system 600 on an opposite side of the main transportation path Z. A second substrate track may be used as a return track for empty substrate carriers. In other embodiments, the substrate carriers may be transported on the substrate track 32 in both directions, as appropriate.

In some embodiments, at least one routing chamber may be configured for rotating at least one mask carrier and at least one substrate carrier at the same time. In some embodiments, at least one routing chamber may be configured for rotating two mask carriers and two substrate carriers at the same time. Accordingly, when a new mask device is to be provided in one of the deposition chambers, the new mask device can be rotated together with the substrate to be coated, whereupon the new mask device and the substrate to be coated can be transported into the deposition chamber synchronously or subsequently from the at least one routing chamber. Mask exchange can be accelerated and processing time can be reduced.

The mask handling assembly 20 may include a robot device, particularly a robot arm, according to any of the embodiments described herein. The robot device may be arranged at a distance of 1 m or less, particularly 1.5 m or less from the mask track 31 which may extend along the main transportation path Z of the vacuum system. In some embodiments, whereas the substrates may be loaded into the vacuum system and unloaded from the vacuum system at a front end and/or at rear end of the main transportation path Z, the mask handling assembly 20 can be provided at a side of the main transportation path Z so that the mask devices can be loaded into the vacuum system and/or unloaded from the vacuum system in a central portion of the main transportation path Z.

According to a further aspect of the present disclosure, a mask carrier for transporting a mask device through a vacuum system is described, wherein the mask carrier can carry a mask device on either of two mask holding sides of the mask carrier. Such a mask carrier can be used in a more flexible manner, because a mask device can be attached to either side thereof, and there is no need to turn or rotate the carrier before a mask attachment.

The mask carrier according to embodiments described herein may include a carrier body with a first mask holding side and a second mask holding side opposite the first mask holding side, a mask holding mechanism configured for holding a mask device at the first mask holding side in a non-horizontal orientation and for holding a mask device at the second mask holding side in a non-horizontal orientation, and a guided portion configured to be guided along a mask track.

For example, the mask carrier may include a first guided portion to be guided along a mask track at a lower part of the carrier body and/or a second guided portion to be carried by a magnetic levitation system at an upper part of the carrier body.

In some embodiments, which may be combined with other embodiments described herein, the mask holding mechanism may include a first connection device provided at the first mask holding side and a second connection device provided at the second mask holding side. The first connection device and/or the second connection device may include at least one of a plurality of screws, bolts, clamps, and pins configured for attaching a mask device to the respective mask holding side. For example, a first mask device may be attached to the first mask holding side and a second mask device may be attached to the second mask holding side via a plurality of screws or clamps, respectively.

In some embodiments, which may be combined with other embodiments described herein, the mask holding mechanism may include a plurality of magnets configured for attracting a mask device toward the first mask holding side and/or for attracting a mask device toward the second mask holding side. For example, one magnetic chuck may be provided for either side of the mask carrier. In some embodiments, the carrier body of the mask carrier may include one or more electromagnets and/or permanent magnets which may be fixed to the carrier body or which may be integrated in the carrier body.

In particular, the carrier body of the mask carrier may include one or more permanent magnets with a reversible polarity. For example, the polarity of the one or more permanent magnets can be reversed via an electric impulse. The mask device can be attached to the mask carrier by reversing the polarity of the one or more permanent magnets in a first direction and/or the mask device can be detached from the mask carrier by reversing the polarity of the one or more permanent magnets in a second direction.

In some embodiments, which can be combined with other embodiments described herein, the mask carrier is formed essentially symmetrically with respect to a vertical plane of symmetry extending between the first mask holding side and the second mask holding side. A symmetric mask carrier can be used for transporting a mask device on either side. For example, after detaching the used mask device from the first mask holding side via the second mask handling assembly 422, the mask carrier can be translated to the first mask handling area via a translation mechanism 450, and a mask device to be used can be attached to the second mask holding side of the mask carrier via the first mask handling assembly 421. Accordingly, the flexibility of the mask carriers can be increased, and the transport distances of the mask carriers in the vacuum system can be reduced.

According to another aspect described herein, a method of handling mask devices in a vacuum system is described.

FIG. 12 is a flow diagram illustrating an exemplary mask handling method. In box 910, a mask device to be used is provided in a first mask handling area of a mask handling chamber. For example, a mask device to be used 411 is loaded into the first mask handling area 401 of the mask handling chamber 405 via a mask loading passage. The mask device to be used 411 may optionally be attached to a mask carrier 415 in the first mask handling area 401. Before attaching, the mask device to be used 411 can optionally be rotated to a non-horizontal orientation, and the mask device to be used can be attached to the mask carrier 415 in the non-horizontal orientation.

In box 920, the mask device to be used is transported from the first mask handling area to at least one deposition chamber 406 of the vacuum system, particularly while the mask device to be used is held by the mask carrier in a non-horizontal orientation. For example, in FIG. 9, the mask device to be used 411 can be transported along the first mask track 431 from the first mask handling area of 401 towards the at least one deposition chamber 406 while being held by the mask carrier 415. In some embodiments, the mask device to be used 411 may be transported through at least one transition chamber and/or a routing chamber 408.

In box 930, the mask device to be used 411 may be used for masked deposition on a substrate in the at least one deposition chamber 406 to provide a used mask device. For example, the mask device to be used 411 may be arranged at a predetermined position in the at least one deposition chamber 406, and a substrate may be positioned behind the mask device to be used 411. A material pattern may be evaporated on a surface of the substrate. During deposition, evaporated material may form a condensate on a front surface of the mask device. Accordingly, after masked deposition on a plurality of substrates, it may be beneficial to clean the used mask device 412.

In box 940, the used mask device 412 may be transported from the at least one deposition chamber 406 to a second mask handling area 402 of the mask handling chamber 405, particularly while the used mask device is held by the mask carrier in a non-horizontal orientation. For example, in FIG. 10, the used mask device 412 can be transported along the second mask track 432 from the at least one deposition chamber 406 to the second mask handling area 402 while being held by the mask carrier 415. In some embodiments, the used mask device 412 may be transported through at least one routing chamber and/or at least one transit chamber.

In box 950, the used mask device 412 is handled in the second mask handling area 402 with the second mask handling assembly 422. For example, the used mask device 412 is detached from the mask carrier 415, is stored in a mask magazine and/or is unloaded from the vacuum system, e.g. by moving the used mask device out of the vacuum system via a second load lock chamber 404.

In some embodiments, providing the mask device to be used 411 in box 910 may include loading the mask device to be used into the vacuum system along a mask loading passage that extends in the first mask handling area 401, e.g. via a first load lock chamber 403. For example, the mask device is taken by the first mask handling assembly 421 from a mask magazine that is arranged in the first load lock chamber 403. The first mask handling assembly 421 may then move the mask device into the mask handling chamber.

Alternatively or additionally, in box 950, handling the used mask device 412 in the second mask handling area 402 may include unloading the used mask device from the vacuum system along a mask unloading passage. The mask unloading passage may be spaced apart from the mask loading passage. For example, the mask unloading passage and the mask loading passage may be provided on opposite sides of the mask handling chamber. For example, the mask handling assembly may move the mask device from the mask handling chamber into a second mask magazine for used masks that is arranged in the second load lock chamber 404.

According to some embodiments, which may be combined with other embodiments described herein, the mask device to be used 411 may be attached to a mask holding side of the mask carrier 415 by the first mask handling assembly 421, before the mask device to be used 411 is transported in box 920. Alternatively or additionally, the used mask device 412 may be detached from the mask holding side of the mask carrier 415 by the second mask handling assembly 422 in the second mask handling area 402 after the transport into the second mask handling area.

In optional box 960, the mask carrier 415 may be transferred from the second mask handling area 402 to the first mask handling area 401 after detaching the used mask device 412 from the mask carrier. For example, a translation mechanism 450 may be provided in the mask handling chamber 405 for a direct transport of mask carriers between the first mask handling area and the second mask handling area, particularly in a transferred direction essentially perpendicular to the direction of the mask tracks.

In optional box 970, a further mask device to be used may be attached to a second mask holding side of the mask carrier 415 opposite the mask holding side in the first mask handling area. In particular, after transferring the mask carrier 415 from the second mask handling area in the first mask handling area, the second mask holding side of the mask carrier may be directed toward the first mask handling assembly 421 so that the first mask handling assembly 421 can attach the further mask device to the second mask holding side. A mask carrier configured for carrying a mask device on either side according to embodiments described herein can be used. Mask transport can be accelerated.

While the foregoing is directed to embodiments of the disclosure, other and further embodiments of the disclosure may be devised without departing from the basic scope thereof, and the scope thereof is determined by the claims that follow.

1. A method of handling a mask device in a vacuum system, comprising:
loading a mask device into a vacuum system;
rotating the mask device from a second orientation to a non-horizontal orientation;
attaching the mask device to a mask carrier in the vacuum system; and
transporting the mask carrier and the mask device in a non-horizontal orientation along a transport path in the vacuum system.

2. A method of handling a mask device in a vacuum system, comprising:
transporting a mask carrier that holds a mask device in a non-horizontal orientation along a transport path in a vacuum system;
detaching the mask device from the mask carrier in the vacuum system;
rotating the mask device from the non-horizontal orientation to a second orientation; and
unloading the mask device from the vacuum system.

3. A method of handling a mask device according to claim 1, further comprising:
detaching the mask device from the mask carrier in the vacuum system; and
unloading the mask device from the vacuum system.

4. (canceled)

5. The method of claim 1, wherein at least one of the following applies: the non-horizontal orientation is an essentially vertical orientation, and the second orientation is an essentially horizontal orientation.

6. The method according to claim 1,
wherein at least one of the following applies: loading the mask device into the vacuum system comprises moving the mask device through a closable opening from a load lock chamber into a mask handling chamber; and
unloading the mask device from the vacuum system comprises moving the mask device through a closable opening from a mask handling chamber into a load lock chamber.

7. The method according to claim 6, wherein the mask device is translated through the closable opening in a side wall of the mask handling chamber into or from a mask magazine that is configured to store a plurality of mask devices and is arranged in the load lock chamber.

8. The method according to claim 1, wherein the mask device is held at the mask carrier by a magnetic force.

9. The method of claim 8, wherein the mask carrier comprises one or more permanent magnets configured for holding the mask device at the mask carrier in the non-horizontal orientation.

10. The method according to claim 9, wherein at least one of attaching the mask device to the mask carrier and detaching the mask device from the mask carrier includes reversing a polarity of at least one permanent magnet of the mask carrier.

11. The method according to claim 1, wherein the mask device is at least one of: attached, detached, moved, translated and rotated by a mask handling assembly.

12. The method according to claim 11, wherein the mask device is at least one of: attached, detached, moved, translated and rotated by a robot arm that is configured for holding the mask device by a magnetic force.

13. The method according to claim 10, wherein the mask handling assembly supplies the mask carrier with at least one of an electric current and with an electric signal when the mask handling assembly is in a position for at least one of detaching and attaching the mask device.

14. A mask handling assembly for handling a mask device in a vacuum system, comprising:
a mask holding portion configured for holding a mask device;
a first actuator configured for moving the mask holding portion;
a second actuator configured for a rotational movement of the mask holding potion between a non-horizontal orientation and a second orientation different from the non-horizontal orientation; and
a handover mechanism configured for transferring the mask device in the non-horizontal orientation between the mask holding portion and a mask carrier.

15. (canceled)

16. The mask handling assembly according to claim 13, wherein the handover mechanism is configured for initiating at least one of an attachment of the mask device to the mask carrier and a detachment of the mask device from the mask carrier.

17. The mask handling assembly according to claim 16, wherein the handover mechanism is configured for initiating at least one of an attachment of the mask device to the mask carrier and a detachment of the mask device from the mask carrier by reversing a polarity of at least one permanent magnet provided at the mask carrier.

18. A vacuum system for depositing a material on a substrate, comprising:
a mask handling chamber;
a load lock chamber;
a closable opening provided between the mask handling chamber and the load lock chamber; and
a mask handling assembly comprising:
a mask holding portion configured for holding a mask device;
a first actuator configured for moving the mask holding portion;
a second actuator configured for a rotational movement of the mask holding potion between a non-horizontal orientation and a second orientation different from the non-horizontal orientation; and
a handover mechanism configured for transferring the mask device in the non-horizontal orientation between the mask holding portion and a mask carrier;
wherein the first actuator of the mask handling assembly is configured for moving the mask holding portion between the mask handling chamber and the load lock chamber through the closable opening.

19. A vacuum system for depositing a material on a substrate, comprising:
a mask handling chamber, at least one deposition chamber, and a mask transportation system configured for transporting mask devices to be used and used mask devices in a non-horizontal orientation between the mask handling chamber and the at least one deposition chamber, wherein the mask handling chamber comprises
a mask handling assembly comprising:
a mask holding portion configured for holding a mask device;
a first actuator configured for moving the mask holding portion;
a second actuator configured for a rotational movement of the mask holding potion between a non-horizontal orientation and a second orientation different from the non-horizontal orientation; and
a handover mechanism configured for transferring the mask device in the non-horizontal orientation between the mask holding portion and a mask carrier,
which is configured for handling at least one of the mask devices to be used and the used mask device.

20. The vacuum system according to claim 19, wherein the mask transportation system comprises at least one of the following:
a first mask track for guiding mask carriers that hold mask devices to be used from the mask handling chamber toward the at least one deposition chamber; and
a second mask track for guiding mask carriers that hold used mask devices to the mask handling chamber from the at least one deposition chamber.

21. The vacuum system according to claim 20, wherein the mask transportation system further comprises a translation mechanism configured for translating mask carriers within the mask handling chamber between the second mask track and the first mask track.

22. The vacuum system according to any of claim 19, further comprising:
a substrate transportation system configured for transporting substrates along a substrate transportation path in the vacuum system.

23. The vacuum system of claim 22, wherein the substrate transportation path extends through or past the mask handling chamber.

24. The vacuum system according to any of claim 19, further comprising:
a second deposition chamber; and
a routing chamber positioned between the mask handling chamber, the at least one deposition chamber and the second deposition chamber, wherein the routing chamber comprises:
a routing device configured for routing the mask devices between the mask handling chamber and the at least one deposition chamber, and between the mask handling chamber and the second deposition chamber.

25. A method of handling mask devices in a vacuum system, comprising:
providing a mask device to be used in a first mask handling area of a mask handling chamber;
rotating the mask device to be used to a non-horizontal orientation;
transporting the mask device to be used from the first mask handling area to at least one deposition chamber of the vacuum system;
using the mask device to be used for masked deposition on a substrate in the at least one deposition chamber to provide a used mask device; and
transporting the used mask device from the deposition chamber to a second mask handling area of the mask handling chamber.

26. The method of handling mask devices of claim 25, wherein at least one of the mask device to be used and the used mask device is held by a mask carrier in a non-horizontal orientation during transport.
